(19) United States
(12) Patent Application Publication
(10) Pub. No.: US 2009/0049414 A1
(43) Pub. Date: Feb. 19, 2009

(54) METHOD AND SYSTEM FOR REDUCING VIA STUB RESONANCE

(75) Inventors: Bhyrav M. MUTNURY, Austin, TX (US); Moises Cases, Austin, TX (US); Wallace G. Tuten, Georgetown, TX (US); Erdem Matoglu, Austin, TX (US)

Correspondence Address: IBM RP-RPS;SAWYER LAW GROUP LLP, 2465 E. Bayshore Road, Suite No. 406, PALO ALTO, CA, 94303, US

(73) Assignee: International Business Machines Corporation, Armonk, NY (US)

(21) Appl. No.: 11/840,075

(22) Filed: Aug. 16, 2007

(51) Int. Cl. G06F 17/50; H05K 1/11

(52) U.S. Cl. 716/2; 174/262

(57) ABSTRACT

Reducing via stub resonance in printed circuit boards. In one aspect, a method for reducing via stub resonance in a circuit board includes determining that resonance exists for a signal to be transmitted through a signal via extending across a plurality of layers in the circuit board. The resonance is caused by a via stub of the signal via, the via stub extending past a layer connected to the signal via. A location is determined for a ground via to be placed relative to the signal via, the location of the ground via being determined based on reducing the resonance for the signal to be transmitted in the signal via.

### FIELD OF THE INVENTION

The present invention relates to printed circuit boards, and more particularly to via connections between layers in printed circuit boards.

### BACKGROUND OF THE INVENTION

Printed circuit boards are used extensively in computer systems and electronic devices. Circuit boards include many individual components that are interconnected by conductive traces etched on the printed circuit board. Since many applications such as servers and other complex devices have many connections and components, it is generally not possible to provide all the components and connecting traces on one layer of the circuit board. Thus, multiple layers are provided in the circuit board, each layer including its own traces and connected to other layers by signal vias (via transitions) that extend perpendicularly through different layers of the circuit board. A via is a copper (or other metal) barrel or cylinder which connects signal traces on one layer to signal traces on another layer. Efficiently-placed signal vias allow more efficient placement of components and less layers to be used. Generally, multiple signal layers are provided for routing signals, and the signal layers are referenced to layers such as ground layers and VDD (power) layers.

The greater the number of layers used in a circuit board, the thicker and more expensive the board becomes. For example, some circuit boards can have as many as eight or even 30 layers. Connecting signal layers that are separated by many board layers can be difficult. One method is to provide “blind” or “buried” vias, which directly connect the two desired layers. However, this practice can be very expensive, since each via must be tailored to the exact length between the layers it is connecting. A second practice is to provide, for each via connection, a long via that extends from the top of the board all the way to the bottom of the board, and to connect only the two desired layers using the long via. Thus the size of the vias are standardized and easier and cheaper to manufacture.

High frequency signals commonly used in servers and other electronic devices can create problems in signal transmission when using circuit boards with vias due to parasitic effects. One cause of poor signal quality is an impedance mismatch or discontinuity between via impedance and the impedance of the transmission line, which results in signal reflections. Another cause of poor signal quality is resonance from via stubs, which may have a more significant effect on signal integrity than impedance mismatch at high frequencies.

A problem with the second practice of providing long vias is that a long unused portion of a long via, i.e. a via stub, may “dangle” and cause via stub resonance. For example, a trace on a first layer is connected to a long via that extends throughout the thickness of the board. Another signal trace is provided on a second layer one layer down from the first layer and connected to the via. A remaining, unused portion of the long via, i.e., a via stub, extends down from the second layer to the bottom of the board. At high frequencies of signals, this stub of the via behaves as a transmission line and resonates, which can create some severe attenuation (loss) in the transmission signal if the stub resonance occurs in the frequency band of operation. The longer the length of the via stub, the lower the resulting resonant frequency, and the greater the chance that the signals will be affected.

One way that via stub resonance can be reduced is by “back drilling” via stubs. This technique uses a drill of a radius slightly larger than the via to drill out and remove the copper in the vias from the bottom portion of the circuit board, to reduce the length of the stub and thus reduce the resonance effects on signals. All the high speed circuits on the board can be routed on the higher layers of the board, allowing back drilling at a constant length for all vias; or back drilling can be performed at multiple different lengths based on particular signals (and causing more expense). However, back drilling can be an expensive procedure and can reduce the manufacturing yield of circuit boards.

Accordingly, what is needed is the ability to reduce the effects of via stub resonance on signal transmission in a multi-layered circuit board without having to perform expensive procedures such as back drilling. The present invention addresses such a need.

### SUMMARY OF THE INVENTION

The invention of the present application relates to reducing via stub resonance in printed circuit boards. In one aspect of the invention, a method for reducing via stub resonance in a circuit board includes determining that resonance exists for a signal to be transmitted through a signal via extending across a plurality of layers in the circuit board. The resonance is caused by a via stub of the signal via, the via stub extending past a layer connected to the signal via. A location is determined for a ground via to be placed relative to the signal via, the location of the ground via being determined based on reducing the resonance for the signal to be transmitted in the signal via.

In another aspect, a system for reducing via stub resonance in a circuit board includes a printed circuit board, a signal via provided in the printed circuit board and a ground via in the circuit board. The signal via connects a first conductive trace on a first layer to a second conductive trace on a second layer different than the first layer, and includes a via stub extending past one of the first layer and second layer. The ground via connects to a ground layer of the printed circuit board, where the ground via is positioned at a location relative to the signal via that minimizes a resonance in a signal transmitted through the signal via.

The present invention allows resonance in signal vias caused by via stubs to be significantly reduced, thus increasing signal strength and reducing attenuation in vias without having to perform elaborate and time consuming procedures such as back drilling via stubs.

### BRIEF DESCRIPTION OF THE FIGURES

FIGS. 1A and 1B are side elevational views of printed circuit boards of the prior art including via stubs;

FIG. 2 a graph illustrating the effects of resonance from via stubs for various different stub lengths;

FIG. 3A is a schematic diagram illustrating impedance relationships for a transmission line as related to the present invention;

FIGS. 3B and 3C are diagrammatic illustrations of two conductors which have capacitance coupling and loop inductance which can be determined for use with the present invention;

FIG. 4 is a top plan view of a portion of a circuit board including vias in accordance with one embodiment of the present invention;

FIG. 5 is a side elevational view of a portion of a circuit board including vias in accordance with one embodiment of the present invention;

FIG. 6 is a top plan view of a portion of a circuit board including differential signal vias in accordance with an embodiment of the present invention;

FIG. 7 is a graph illustrating resonance in a transmission signal using the ground vias of the present invention;

FIGS. 8A and 8B are diagrammatic illustrations of the energy distribution in the via configurations of the present invention; and

FIG. 9 is a flow diagram illustrating a method of the present invention for providing ground vias to reduce resonance in signal transmission through vias having via stubs.

### DETAILED DESCRIPTION

The present invention relates to printed circuit boards, and more particularly to via connections between layers in printed circuit boards. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

The present invention is mainly described in terms of particular systems provided in particular implementations. However, one of ordinary skill in the art will readily recognize that this method and system will operate effectively in other implementations. For example, the system implementations usable with the present invention can take a number of different forms. The present invention will also be described in the context of particular methods having certain steps. However, the method and system operate effectively for other methods having different and/or additional steps not inconsistent with the present invention.

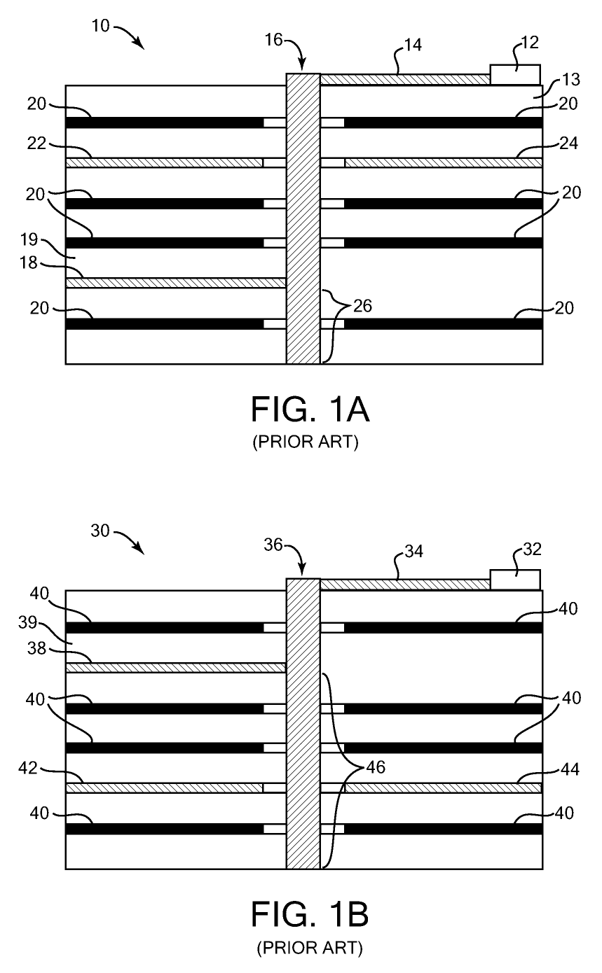

To more particularly describe the features of the present invention, please refer to FIGS. 1A-9 in conjunction with the discussion below.

FIG. 1A is a side elevational view of a prior art printed circuit board 10 including a via stub. A connector pad 12 on the top layer 13 of the board 10 is connected to a trace 14 on the top of the board. Trace 14 is connected to a long via 16 that extends throughout the thickness of the board 10. A signal trace 18 is provided on a layer 19 several (e.g., five) layers down from the top layer 13, where the signal trace 18 is connected to the via 16. Other layers include planes 20, which can be power (VDD) and ground planes, and other signal traces 22 and 24, none of which are connected to the via 16.

A remaining, unused portion 26 of the long via 16, i.e., a via stub 26, extends down from trace 18 to the bottom of the board 10. At high frequencies of signals, especially when 1/10^{th} of the wavelength for a signal frequency is smaller than the via stub length, this stub portion of the via behaves as a transmission line and may start resonating, like an antenna. A sudden change can be induced in the loss characteristics of the transmission channel. This can create some severe attenuation (loss) in the transmission signal if the stub resonance occurs in the frequency band of operation.

The longer the length of the via stub, the more significant the effect of via stub resonance. FIG. 1B is a side elevational view of another example of a printed circuit board 10 including a longer via stub. Connector pad 32 is connected to a trace 34 on the top of the board. Trace 34 is connected to a long via 36, and a signal trace 38 is connected to the via 36 and is provided on a layer 39 two layers down from the top layer. Other layers include planes 40 and other signal traces 42 and 44. In FIG. 1B, the via stub 46 of the long via 36 extends down from trace 38 to the bottom of the board 10, and is much longer than the via stub 26 shown in FIG. 1A. Therefore, the resonance from via stub 46 occurs at a lower frequency, which more strongly impacts signals than the shorter stub 26 in the board of FIG. 1A.

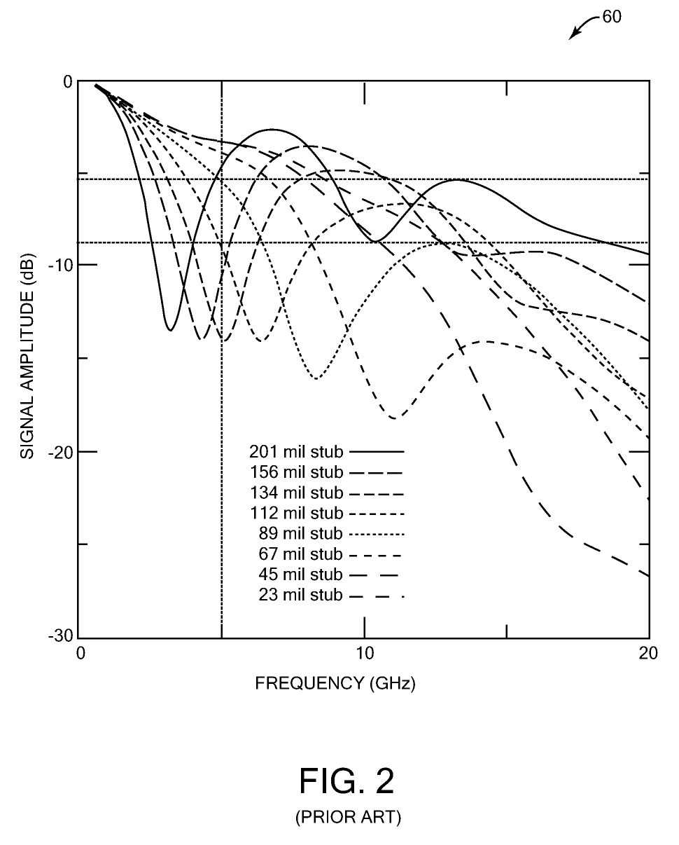

FIG. 2 is a graph 60 illustrating the effects of resonance from via stubs for various different stub lengths. The curves of FIG. 2 ideally go down with higher frequency in an approximately linear fashion, but instead are shown to oscillate due to via stub resonance. It can be seen from FIG. 2 that the longer the via stub, the smaller the via resonant frequency. For example, for frequencies near 3-5 Ghz and with stub lengths of 100 to 200 mils, the signal will be greatly attenuated due to the resonance. The signal attenuation is a function of stub length, signal frequency and materials used in the transmission of signals and in vias.

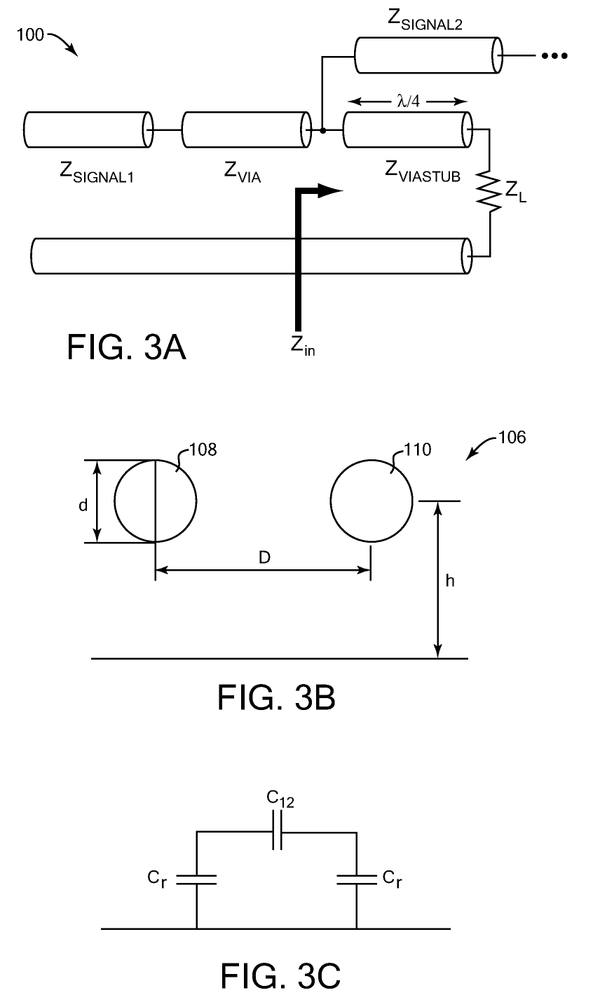

FIG. 3A is a schematic diagram 100 illustrating impedance relationships for a transmission line as related to the present invention. A via stub resonates because it behaves like a transmission line. As indicated in FIG. 3A, the input impedance Zin looking into the via stub is:

$${Z}_{i n} = {Z}_{viastub} \frac{{Z}_{L} + j {Z}_{viastub} tan β l}{{Z}_{viastub} + j {Z}_{L} tan β l} \qquad ( 1 )$$

where 1 is the length of the via, and β is the propagation constant.

When

l=λ/4, tan βl→∞

### Hence,

$${Z}_{i n} = \frac{{Z}_{vai}^{2}}{{Z}_{L}} \\ For via {Z}_{L} = ∞ ⇒ {Z}_{i n} = 0 \qquad ( 2 )$$

When Zin=0, the reflection coefficient is −1. This indicates that there is no transmission. This is the reason why there is a sudden dip in attenuation at a quarter wavelength. The quarter wavelength frequency is given by:

$$\begin{matrix}f = \frac{1}{4 * t} \\ where & ( 3 ) \\ t = \frac{\sqrt{{ɛ}_{r}}}{C} * l & ( 4 )\end{matrix}$$

and C is the velocity of light, l is the length of the via, and εᵣ is the dielectric constant of the material of the circuit board.

From the above, it is known that the resonance at a quarter wavelength is a function of the via length. This is the reason that back drilling is effective, since it decreases the via length, which in turn moves the resonance frequency beyond the frequency band of interest.

The embodiments described below do not eliminate the resonance frequency points. The invention mitigates the impact of the magnitude of resonance throughout the frequency of interest by providing better current distribution. Thus the expensive procedure of back drilling can be avoided.

FIG. 3B is a diagrammatic illustration 106 of two conductors 108 and 110 which, as vias, have capacitance coupling and loop inductance which can be determined for use with the embodiments of the present invention.

For example, the capacitance coupling between the conductors 108 and 110 can be determined using the formula:

$${C}_{12} = \frac{2 π ɛ \cdot ln \sqrt{{( \frac{2 h}{D} )}^{2} + 1}}{ln \{ ( \frac{4 h}{d} ) \cdot \sqrt{{( \frac{2 h}{D} )}^{2} + 1} \} ln \{ ( \frac{4 h}{d} ) / \sqrt{{( \frac{2 h}{D} )}^{2} + 1} \}} … [ F / m ] \qquad ( 5 )$$

where d is the diameter of each conductor, D is the distance between the centers of the two conductors 108 and 110, and h is the distance from the centers of the conductors 108 and 110 to the reference plane (where h in the case of vias is typically a very large number). C12 is the capacitance between the two conductors, as indicated in FIG. 3C.

An example of the loop inductance between the conductors 108 and 110 is provided in the formula below:

$$L = \frac{μ l}{π} ( ln ( \frac{2 D}{d} ) - \frac{D}{l} ) \qquad ( 6 )$$

The capacitive coupling and loop inductance can thus be estimated or determined between two conductors in a printed circuit board. Using the inductance and capacitance, the resonant frequency can be determined by the formula:

$$ω = \frac{1}{\sqrt{LC}} \qquad ( 7 )$$

where ω=2πf (f is the resonance frequency in Hertz), L is the inductance, and C is the capacitance.

The present invention can mitigate the effects of resonance by manipulating the inductance and capacitance related to a signal via, as described in detail below.

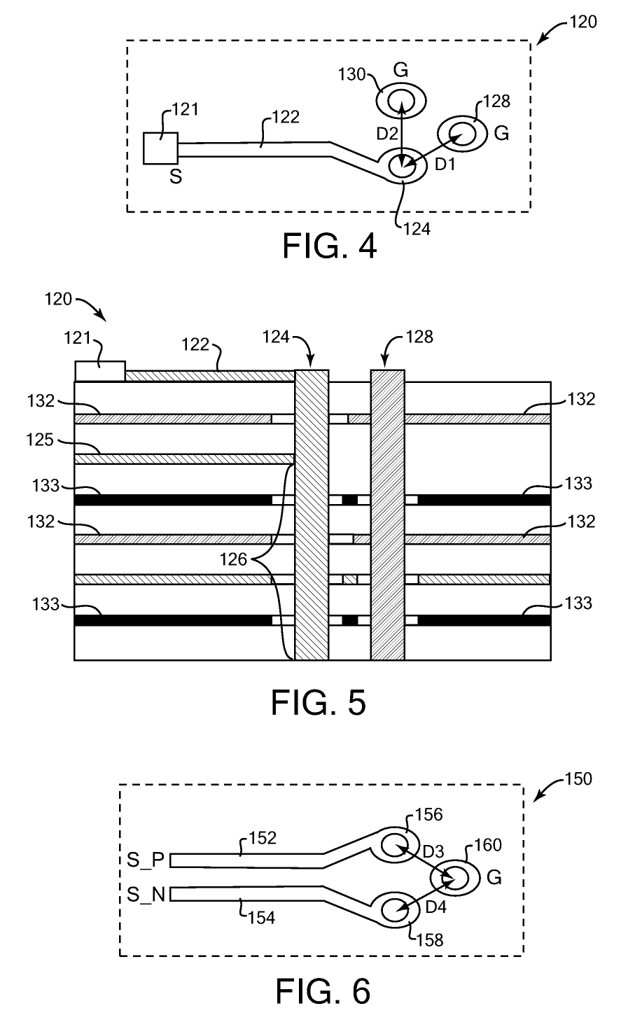

FIG. 4 is a top plan view of a portion of a circuit board 120 including vias in accordance with one embodiment of the present invention. FIG. 5 is a side elevational view of the circuit board 120.

An existing signal trace 122 can be connected to a connector pad 121 or other circuit trace feature on a layer of the circuit board 120. In the example shown, the trace 122 and pad 121 are on the top of the board, but can be at other layers in other embodiments. Trace 122 is connected to a single-ended signal via 124 provided in the board 120. Via 124 extends down through the thickness of the board 120 and connects one or more other traces 125 positioned on layer(s) one or more layers away in board 120 from the layer of trace 122. Other ground layers 132 and power layers 133 are also provided in the circuit board. Via 124 has a via stub 126 of sufficient length to cause resonance and potential attenuation in the transmission of signals through the traces 122 and 125 and via 124.

Ground vias 128 and/or 130 of the present invention are provided near to the signal via 124. In some embodiments, only one ground via 128 or 130 is provided, while in other embodiments both ground vias 128 and 130 are included. Further additional ground vias can be provided in other embodiments. Ground vias 128 and 130 are standard ground vias that extend through the entire thickness of the circuit board 120 and are connected to the ground layers 132 of the circuit board 120.

Ground vias 128 and/or 130 add a return current path for signal transmitted through the signal via 124 and change the capacitance and inductance for the signal via 124. Every signal needs a return path, which is typically provided by ground, to complete its current loop. However, in previous circuit boards, the current return path is at least partially through the circuit board itself, and/or can often be distorted due to ground planes and ground vias placed at arbitrary locations relative to signals, traces, and vias. Distorting a current return path in a high frequency signal design can be as detrimental to a signal as distorting the transmission line or signal itself. Such distorted return paths can provide a lopsided or uneven energy distribution in the conductive vias, leading to attenuation in the signals.

The ground vias of the present invention fix the reference points for the signal such that there is an improved current return path for the signals using the signal via 124, where the return path is through the ground vias 128 and/or 130. This provides better current distribution and thus a stronger signal through the signal via, reducing the attenuation effect of resonance.

The ground vias 128 and 130 also reduce the resonance of the signals transmitted through the signal via 124 and its via stub. By controlling the capacitance coupling and loop inductance between the signal via and the added ground via(s), the resonant frequency can be changed. This capacitance and inductance can be controlled, for example, by placing the ground vias 128 and/or 130 a determined distance D from the signal via 124.

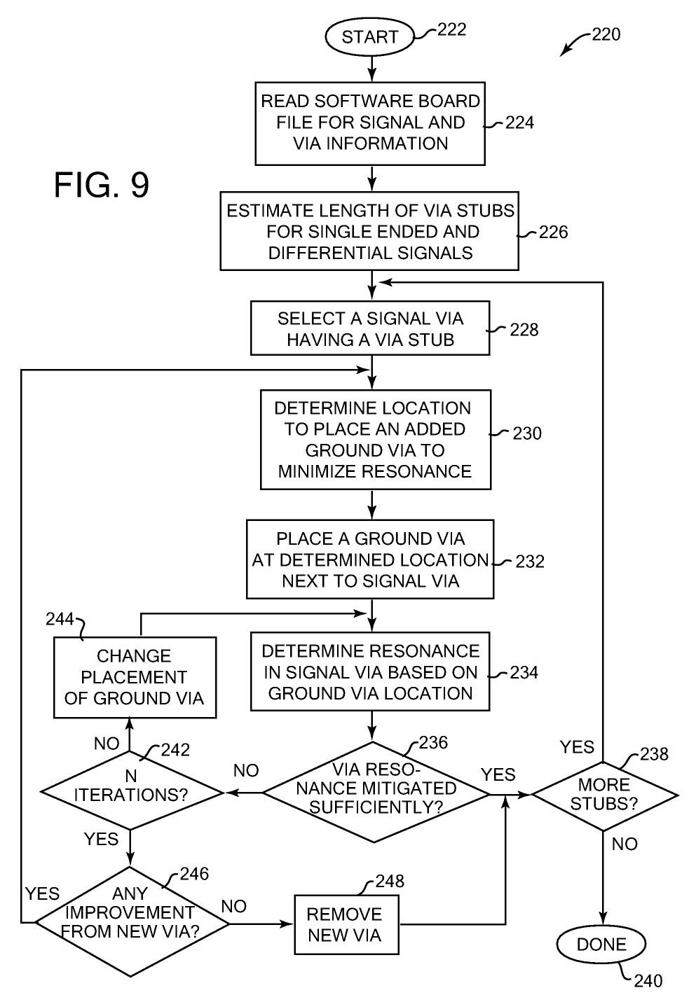

As shown in FIG. 4, the placement of the ground vias 128 and/or 130 are near the signal via 124, the distance D from the signal via 124. The distance D has been determined to be effective at equalizing current distribution and reducing the resonance caused by the via stub 126. Different ground vias 128 and 130 may be placed at different distances D1 and D2, and at different locations relative to the signal via 124. The distance D and location of the ground via 128 and/or 130 relative to the signal via 124 depends on the particular implementation, and is dependent on the frequencies of signals and the physical characteristics (such as dimensions, materials, etc.) of the circuit board and vias. A method for determining the placement of the ground vias 128 and/130 is described below with respect to FIG. 9.

Other embodiments can provide additional ground vias similar to vias 128 and 130. In addition, other embodiments can provide additional signal vias 124 which also make use of the ground vias 128 and 130, i.e., the ground vias 128 and/or 130 can provide current return paths for multiple signal vias 124.

The additional ground vias 128 and/or 130 provide an improved current return path for signals using the signal vias and reduce the resonance at the frequency band for those signals, and thus mitigate the magnitude of resonance caused by a long via stub at high frequencies. The present invention mitigates the effects of resonance throughout the frequency band of interest without having to back drill any via stubs or otherwise reduce stub length.

FIG. 6 is a top plan view of a portion of a circuit board 150 including differential signal vias in accordance with an embodiment of the present invention. A first signal trace 152 transmits a P component of a signal, and a second signal trace 154 transmits an N component of a signal. In the example shown, the traces 152 and 154 are on the top of the board, but can be on other layers in board 150 in other embodiments. Trace 152 is connected to a signal via 156 provided in the board 150, and trace 154 is connected to a signal via 158. Vias 156 and 158 extend down through the thickness of the board 150 and connect one or more other traces positioned on layer(s) one or more layers away in board 150, similarly to the via 124 as shown in FIG. 5. Via 156 and/or via 158 has a via stub of sufficient length to cause resonance and potential attenuation in the transmission of signals through the trace 152 and via 156, and the trace 154 and via 158, respectively.

A ground via 160 of the present invention is provided near to the signal vias 156 and 158. In some embodiments, only one ground via 160 is provided, while in other embodiments additional ground vias are provided near the signal vias 156 and 158. Ground via 160 is a standard ground via that extends through the entire thickness of the circuit board 150 and are connected to the ground layers of the circuit board 150. Similarly to the ground vias 128 and 130 of FIG. 3, ground via 160 is provided at a determined distance D3 from signal via 156 and a determined distance D4 from signal via 158 such that the ground via 160 provides an improved return current path for signals transmitted through the vias 156 and 158 and reduces the resonance of signals in the signal vias 156 and 158.

The distances D3 and D4 have been determined to be effective at equalizing current distribution and reducing the resonance caused by the via stubs. One or more ground vias 160 may be placed at different distances and at different positions relative to the signal vias 156 and 158. The distances and position of the ground via 160 relative to the signal vias depends on the particular implementation, and can be determined similarly to determining the placement of the ground vias for a single ended via as described with respect to FIG. 9. Depending on the characteristics of the board 150 and materials and characteristics (e.g. dimensions) of the components, D3 and D4 can be the same distance, or different, depending on which distances and locations provide a minimum resonance in the signal in the vias 156 and 158.

Other embodiments can provide additional ground vias similar to via 160. In addition, other embodiments can provide additional signal vias which also make use of the ground via 160 to reduce resonance in signals though those additional signal vias.

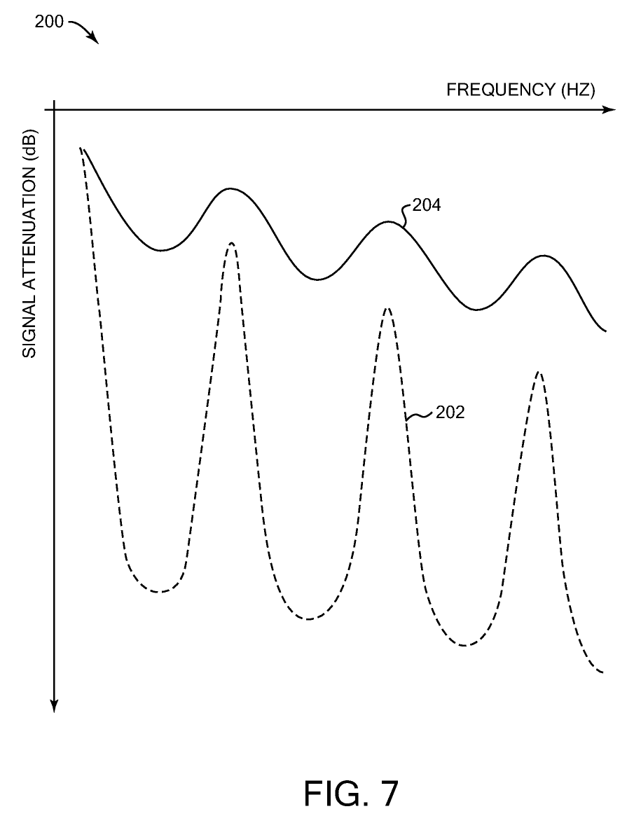

FIG. 7 is a graph 200 illustrating resonance in a transmission signal using the ground vias as described above in the single ended configuration of FIGS. 4 and 5. Graph 200 illustrates the signal attenuation of the signal in dB (vertical axis) transmitted through the via at various frequencies (horizontal axis). A first curve 202 shows the oscillation and attenuation when no ground vias 128, 130, or 160 are used, so that the via stub of the via 124 causes resonance.

A second curve 204 shows the oscillation and attenuation when ground vias 128 and 130 are provided. In one embodiment of the invention, the ground via(s) are placed by examining the amplitude of resonance in the signal resulting from the via stub, and placing the ground vias where the resonance amplitude is sufficiently reduced. As shown by curve 204, the amplitude of attenuation from resonance is significantly reduced when the ground via(s) 128 and 130 are provided, such that resonance will not impact channel loss characteristics significantly. Not only is all attenuation lower, the extent of the oscillation (peak to peak variation) is much lower than the oscillation shown in curve 202.

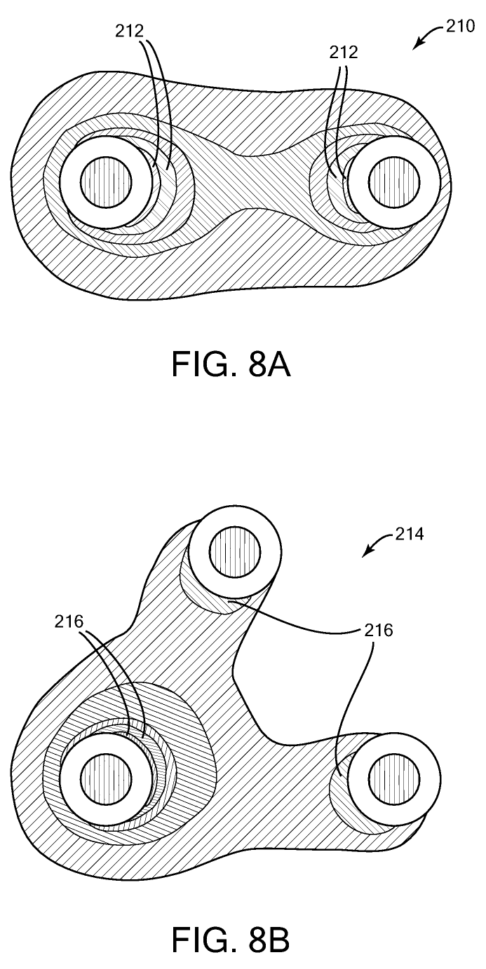

FIG. 8A is a diagrammatic illustration 210 of the energy distribution in the single ended via and ground via configuration of FIGS. 4 and 5, in which there is a single ground via 128. As shown, the energy is mostly concentrated in higher energy zones 212 within and around the signal via 124 itself and in the ground via 128. The remaining regions of the via barrel do not conduct current uniformly. Thus the return current path of signals transmitted through the vias is improved.

FIG. 8B is a diagrammatic illustration 214 of the energy distribution in the single ended via configuration of FIGS. 4 and 5, in which there are two ground vias 128 and 130. The current return path is improved even more than in the embodiment of FIG. 8A, since here there are two return current paths. Thus, the energy is more concentrated in higher energy zones 216 in and close around the signal via 124 and in the ground vias 128 and 130.

FIG. 9 is a flow diagram illustrating a method 220 for providing ground vias to reduce resonance in signal transmission through vias having via stubs. Method 220 can be implemented using program instructions or code implemented by a computer or similar electronic device, where the program instructions are stored on a computer readable medium such as semiconductor or solid state memory, magnetic hard disk, magnetic tape, optical disk (CD-ROM, DVD-ROM, etc.), or other medium, and executed by a computer (including other electronic devices).

The method begins at 222, and in step 224, a software board file is read for the signal and via information. A software board file is an electronic file or description of the circuit board, i.e., a software circuit board layout, which includes a description of the board's vias and traces, their positions and physical characteristics, such as their dimensions, dielectric constants, material composition, etc. The software board file, for example, can be read by a computer system and used to edit the circuit board layout. A board file can be used to manufacture the physical circuit board. This board file is read to receive the information for relevant signal traces and vias on the circuit board. Some board characteristics can also be obtained from other sources.

In step 226, the length is estimated for via stubs for differential signals and single ended signals on the circuit board, using the software board file data. Only the relevant via stubs need be examined, which are via stubs that will receive high frequency signals that could be significantly affected by resonance caused by sufficiently long via stubs. The relevant via stubs are examined to determine the via stub lengths. This estimation can be performed for a particular signal via, for example, by determining the layers that the via connects, and determining the physical length of the via stub extending beyond the layer connections.

In step 228, one of the signal vias having an examined via stub from step 226 is selected. If it is a differential signal, both of the differential signal vias (such as signal vias 156 and 158 of FIG. 6) are selected as the “signal via” in step 228. In step 230, a location is determined for placement of an additional ground via on the circuit board to minimize resonance in the selected signal via. This location can be determined by examining different resonance characteristics. In one embodiment, the ground via location is determined as a location that moves the resonant frequency of the signal via to a frequency outside the signal frequency band that will affect the signals through the signal via. For example, a loop inductance and capacitive coupling between the signal via and an additional ground via are estimated which will minimize the resonance in the selected signal via. This desired inductance and capacitance can be estimated using, for example, equations such as those mentioned above for FIGS. 3B and 3C, such that a distance and/or location from the signal via is determined. The estimation can use the length and diameter of the signal via stub and other known via/board characteristics such as dielectric constant and the known frequencies of the signals to be transmitted through the selected signal via. From this information, it can be determined which signal frequencies will resonate in the via, and the distance from the signal via that a ground via can be placed to provide resonance outside the signal frequency band used by the signals, such that the signal resonance in the via stub is minimized and a better current return path is realized. In other embodiments, modeling software, such as 2D or 3D field software, can be used instead of the above equations to estimate the inductance and capacitance and/or the resonant frequencies and distance needed for the ground via to move the resonant frequency outside the signal frequency band that affects the signals.

In a different embodiment, the ground via location is determined in step 230 by examining the magnitude (amplitude) of the resonance in the signal via, and determining a location for the ground via that will reduce or minimize that resonance magnitude. For example, 2D or 3D field modeling software can be used to examine resonance magnitude at various distances and/or determine the location that best minimizes resonance magnitude for the given board layout and signal frequency. This embodiment thus does not need to examine moving the resonant frequency outside the band of interest as in the embodiment above, and similarly the embodiment described above does not need to examine the reduction of resonance magnitude; they are independent examinations and determinations. In still other embodiments, step 230 can combine these two approaches to estimate a ground via location, thus examining moving the resonant frequency away from the signal frequency, as well as reducing the resonance magnitude, to minimize the resonance in the signal via.

In step 232, a ground via is placed on the circuit board in the software board file, the ground via being placed at the location estimated in step 230. In step 234, the resonance in the signal via is determined based on the characteristics and location of the added ground via. This determination can find the resonant frequency for the selected signal via using the relevant simulation characteristics of the circuit board as provided in the board file.

In step 236, from the determination of step 234 it is determined whether the via stub resonance is mitigated sufficiently. For example, in the moving-resonant-frequency embodiment, the frequency of the signal(s) to be transmitted can be compared to the determined resonant frequency. A predetermined threshold frequency range can be used, such that if the resonance frequency is outside that threshold band centered on the desired signal frequency, or outside the frequency range from the desired signal frequency, then the resonance is considered to have been reduced sufficiently. In the magnitude-reduction embodiment, the resonance can be considered sufficiently reduced if the magnitude of the resonance found in step 234 is below a predetermined threshold magnitude. If the mitigation is sufficient, then the process continues to step 238. In step 238, it is checked whether there are more via stubs to be processed to reduce the resonance in the current method, e.g., whether there are any via stubs whose lengths were estimated in step 226 which have not yet been affected by added ground vias of step 232. If so, then the process returns to step 228 to select another signal via having a via stub. If all the relevant via stubs have been processed by method 220 at step 238, then the process is complete at 240.

If the mitigation of resonance is not sufficient as checked in step 236, then in step 242 it is checked whether N iterations have been completed. Each such iteration places or moves the added ground via to a different location and checks whether the resonance is sufficiently mitigated at the desired signal frequency or frequencies (steps 244 and 234). If N iterations have not been completed, then the process continues to step 244 to change the placement of the added ground via on the circuit board in the software board file, i.e., move the added ground via to a new location. The location can be changed by a predetermined amount in a predetermined direction, e.g., a particular increment distance moved toward the signal via (then in later iterations, for example, moved away from the via, then moved to a location between the two locations already tested, etc.). In some embodiments, the change in placement can also be guided by previous placements, e.g., if the previous placement in one direction made the resonance worse, then the ground via can be moved in the opposite direction. Any other mathematical optimizations can also be included in the change in placement. In addition, some embodiments can examine the resulting resonance found in step 234 and determine therefrom an amount of distance and direction that the ground via should moved based on estimated capacitance and inductance calculations and/or resonance magnitude calculations. The process then returns to step 234 to determine the resonance at the new location of the added ground via, and check if resonance is sufficiently reduced at step 236. The number N can be any number found to provide a worthwhile reduction in resonance without having to perform an inordinate number of placement iterations.

If N placement iterations have been completed in step 242, then the process continues to step 246, where it is checked whether there is any improvement in the resonance of the signal via resulting from a newly added ground via compared to the resonance resulting from the last added ground via. More ground vias after the first can be added if changing the placement of the previously-added via(s) does not mitigate resonance sufficiently. However, in some cases, even after adding such an additional ground via and optimizing its placement in iterations of step 244, the resonance may stay the same and not be reduced compared to the resonance resulting from the previous added ground via. If that occurs, it is not worthwhile to continue attempting to reduce resonance. Thus, if the result of step 246 for an additional ground via is negative, the process continues to step 248 to remove that newly added ground via, and the process for the current stub exits by continuing to step 238 to select another via stub.

If, however, an improvement in resonance occurred for the placement-optimized new ground via (or if the added ground via is the first to be added), then the process returns to step 230 to estimate the location of a new, additional ground via based on minimizing resonance, and place that new ground via next to the signal via in step 232. Since, after N iterations of moving the previously-added ground via, the desired reduction in resonance in the signal via was not achieved, another ground via is added to reduce the resonance further. The resulting resonance in the signal via can then be determined in step 234 and the locations of the new ground via and the previously-added ground via(s) can be changed in further iterations if the resonance is not reduced sufficiently, or the process can exit to the next stub through step 246 if no further reduction in resonance is detected from the new via.

After a certain number of placement iterations and/or added ground vias, the desired reduction in resonance is achieved. Then the process returns to step 228 to select another via stub for resonance reduction. Once all via stubs are processed in this way, the process is complete, and the software board file can be used as a template to manufacture a physical circuit board that includes the added ground vias.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for reducing via stub resonance in a circuit board, the method comprising:
determining that resonance exists for a signal to be transmitted through a signal via extending across a plurality of layers in the circuit board, the resonance caused by a via stub of the signal via, the via stub extending past a layer connected to the signal via; and
determining a location for a ground via to be placed relative to the signal via, the location of the ground via being determined based on a reduction of the resonance in the signal to be transmitted in the signal via.

2. The method of claim 1 wherein a loop inductance and a coupling capacitance between the signal via and the ground via are estimated to determine the location of the ground via.

3. The method of claim 2 wherein determining the location for the ground via includes adjusting the inductance and capacitance coupling between the ground via and signal via to change a resonant frequency for the signal such that the resonant frequency is outside a predetermined frequency range from the frequency of the signal.

4. The method of claim 1 wherein determining the location for the ground via includes determining a location that reduces the magnitude of the resonance.

5. The method of claim 1 wherein the ground via improves a return path of current of the signal to be transmitted through the signal via.

6. The method of claim 1 wherein the resonance is determined to be sufficiently reduced when the resonant frequency of the signal has been adjusted to be outside a predetermined range of frequencies surrounding the frequency of the signal.

7. The method of claim 1 wherein determining the location for the ground via includes determining that the location does not reduce the resonance sufficiently and changing the location of the ground via to reduce the resonance further.

8. The method of claim 1 further comprising determining the locations for one or more additional ground vias relative to the signal via, the locations of the additional ground vias being determined based on reducing the resonance for the signal to be transmitted in the signal via.

9. The method of claim 1 wherein an additional signal via located on the printed circuit board also has resonance reduced in signals transmitted through the additional signal via due to the location of the ground via relative to the additional signal via.

10. The method of claim 1 wherein the determining the location for the ground via is performed for a software circuit board layout corresponding to the printed circuit board.

11. A system for reducing via stub resonance in a circuit board, the system comprising:
a printed circuit board;
a signal via provided in the printed circuit board, the signal via connecting a first conductive trace on a first layer to a second conductive trace on a second layer different than the first layer, wherein the signal via includes a via stub extending past one of the first layer and second layer; and
a ground via provided in the printed circuit board and connected to a ground layer of the printed circuit board, wherein the ground via is positioned at a location relative to the signal via that minimizes a resonance in a signal transmitted through the signal via.

12. The system of claim 11 wherein a loop inductance and a coupling capacitance between the signal via and the ground via changes the resonant frequency of the signal through the signal via so that the resonant frequency is outside a predetermined frequency range from the frequency of the signal.

13. The system of claim 11 wherein determining the location for the ground via includes determining a location that reduces the magnitude of the resonance.

14. The system of claim 11 wherein the ground via improves a return path of current of the signal transmitted through the signal via.

15. The system of claim 11 further comprising one or more additional ground vias in the printed circuit board connected to the ground layer, wherein the additional ground vias are positioned at a location relative to the signal via that minimizes a resonance in a signal transmitted through the signal via.

16. The system of claim 11 further comprising an additional signal via located on the printed circuit board also has resonance reduced in signals transmitted through the additional signal via due to the location of the ground via relative to the additional signal via.

17. A computer readable medium storing program instructions to be executed by a computer and for reducing via stub resonance in a circuit board, the program instructions performing steps comprising:
determining that resonance exists for a signal to be transmitted through a signal via extending across a plurality of layers in the circuit board, the resonance caused by a via stub of the signal via, the via stub extending past a layer connected to the signal via; and
determining a location for a ground via to be placed relative to the signal via, the location of the ground via being determined based on a reduction of the resonance in the signal to be transmitted in the signal via.

18. The computer readable medium of claim 17 wherein a loop inductance and a coupling capacitance between the signal via and the ground via are estimated to determine the location of the ground via.

19. The computer readable medium of claim 18 wherein determining the location for the ground via includes adjusting the inductance and capacitance coupling between the ground via and signal via to change the resonant frequency for the signal.

20. The computer readable medium of claim 16 wherein determining the location for the ground via includes determining a location that reduces the magnitude of the resonance.

21. The computer readable medium of claim 17 wherein the resonance is determined to be sufficiently reduced when the resonant frequency of the signal has been adjusted to be outside a predetermined range of frequencies surrounding the frequency of the signal.

22. The computer readable medium of claim 17 wherein determining the location for the ground via includes determining that the location does not reduce the resonance sufficiently and changing the location of the ground via to reduce the resonance further.

23. The computer readable medium of claim 17 further comprising placing one or more additional ground vias relative to the signal via, the locations of the additional ground vias being determined based on reducing the resonance for the signal to be transmitted in the signal via.

24. The computer readable medium of claim 17 wherein an additional signal via located on the printed circuit board also has resonance reduced in signals transmitted through the additional signal via due to the location of the ground via relative to the additional signal via.

25. The computer readable medium of claim 17 wherein the determining the location for the ground via is performed for a software circuit board layout corresponding to the printed circuit board.
